(19) United States
(12) Patent Application Publication
(10) Pub. No.: US 2020/0194235 A1
(43) Pub. Date: Jun. 18, 2020

(54) APPARATUS FOR MANUFACTURING SEMICONDUCTOR DEVICE

(71) Applicant: Samsung Electronics Co., Ltd., Suwon-si (KR)

(72) Inventors: Ki-hwan KIM, Seoul (KR); Yeon-tae KIM, Suwon-si (KR); Kee-soo PARK, Hwaseong-si (KR); Pan-kwi PARK, lncheon (KR); Jin-ah LEE, Hwaseong-si (KR); Chang-yun LEE, Hwaseong-si (KR); Sung-keun LIM, Uiwang-si (KR); Min-ho CHOI, Suwon-si (KR); Eun-sok CHOI, Uiwang-si (KR)

(73) Assignee: Samsung Electronics Co., Ltd., Suwon-si (KR)

(21) Appl. No.: 16/450,059

(22) Filed: Jun. 24, 2019

(30) Foreign Application Priority Data
Dec. 17, 2018 (KR) 10-2018-0163315

(51) Int. Cl. H01J 37/32; C23C 16/455; H01L 21/311; H01L 21/687; H01L 21/67

(52) U.S. Cl. CPC H01J 37/32513; H01J 37/32642; H01J 37/32724; C23C 16/45565; H01J 2237/3341; H01L 21/68742; H01L 21/68735; H01L 21/67248; H01L 21/31116

(57) ABSTRACT

An apparatus for manufacturing a semiconductor device includes: a process chamber including a plasma processing space; and a substrate supporter arranged in the process chamber and configured to support a substrate, wherein the substrate supporter includes: a base including a plurality of lift pin holes, each configured to accommodate a lift pin; and a seal band having a ring shape and protruding from the base, the seal band having an inner diameter that is less than a pitch circle diameter of the plurality of lift pin holes.

### CROSS-REFERENCE TO RELATED APPLICATION

This application claims the benefit of Korean Patent Application No. 10-2018-0163315, filed on Dec. 17, 2018, in the Korean Intellectual Property Office, the disclosure of which is incorporated herein in its entirety by reference.

### BACKGROUND

Example embodiments of the inventive concepts relate to an apparatus for manufacturing a semiconductor device. For example, at least some example embodiments relate to an apparatus for manufacturing a semiconductor device using plasma.

Generally, to manufacture semiconductor devices, a series of processes, such as deposition, etching, and cleaning, may be performed. These processes may be performed by deposition, etching, or cleaning apparatuses that include process chambers. For example, in the case of etching processes using plasma processing techniques, etching apparatuses, which etch material layers on substrates by using plasma such as capacitively coupled plasma or inductively coupled plasma or using a remote plasma source generated outside the process chambers, have been widely used. There are issues in that etching processes using such plasma generally have low etch rates and low etch selectivity.

### SUMMARY

Example embodiments of the inventive concepts provide an apparatus for manufacturing a semiconductor device, the apparatus allowing uniformity in a plasma process, for example, a plasma etching process, to be improved.

Example embodiments of the inventive concepts also provide an apparatus for manufacturing a semiconductor device, the apparatus allowing a material layer to be etched at a high etch rate while having high etch selectivity relative to other material layers in an etching process for the material layer including silicon oxide.

According to an example embodiment of the inventive concepts, there is provided an apparatus configured to manufacture a semiconductor device, the apparatus including: a process chamber having a plasma processing space therein; and a substrate supporter in the process chamber, the substrate supporter configured to support a substrate, the substrate supporter including, a base having a plurality of lift pin holes therein such that the plurality of lift pin holes arranged with a pitch circle diameter, the plurality of lift pin holes each configured to accommodate a lift pin; and a seal band having a ring shape and protruding from the base, the seal band having an inner diameter less than the pitch circle diameter of the plurality of lift pin holes.

According to another example embodiment of the inventive concepts, there is provided an apparatus configured to manufacture a semiconductor device, the apparatus including: a process chamber having a plasma processing space therein; and a substrate supporter in the process chamber, the substrate supporter configured to support a substrate, the substrate supporter including, a base; and a seal band having a ring shape and protruding from the base, the seal band having a constant width in a radial direction thereof

According to yet another example embodiment of the inventive concepts, there is provided an apparatus configured to manufacture a semiconductor device, the apparatus including: a process chamber having a plasma processing space therein; a substrate supporter in the process chamber, the substrate supporter configured to support a substrate; a plasma generator configured to generate plasma; a blocker plate configured to diffuse the plasma supplied from the plasma generator, the blocker plate including a body having first through-holes therethrough, the body being formed of nickel; and a shower head configured to diffuse the plasma jetted via the first through-holes of the blocker plate, the shower head having second through-holes therein, the shower head configured to jet the plasma to the plasma processing space via the second through-holes.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view illustrating an apparatus for manufacturing a semiconductor device, according to example embodiments;

FIG. 2 is a flowchart illustrating an etching method using the apparatus for manufacturing a semiconductor device, which is shown in FIG. 1, and a method of manufacturing a semiconductor device, the method including the etching method;

FIG. 3 is a perspective view illustrating a pedestal plate of a substrate supporter shown in FIG. 1;

FIG. 4 is a plan view of the pedestal plate of the substrate supporter shown in FIG. 1, as viewed from above;

FIG. 5 is a cross-sectional view of the pedestal plate, taken along a line V-V of FIG. 3;

FIG. 6 is a perspective view illustrating a blocker plate according to example embodiments;

FIG. 7 is a cross-sectional view illustrating the blocker plate and a shower head, which correspond to a region VII in FIG. 1;

FIG. 8 is a cross-sectional view illustrating the blocker plate and the shower head, which correspond to a region VIII in FIG. 1; and

FIG. 9 is a cross-sectional view illustrating the blocker plate and the shower head, which correspond to a region IX in FIG. 1.

### DETAILED DESCRIPTION

Hereinafter, example embodiments of the inventive concepts will be described in detail with reference to the accompanying drawings. Like components will be denoted by like reference numerals throughout the specification, and repeated descriptions thereof will be omitted.

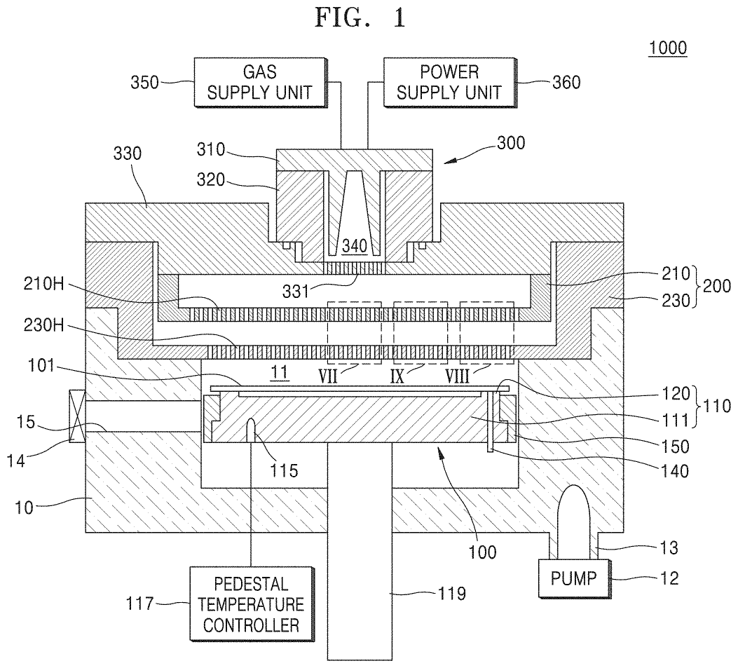

FIG. 1 is a cross-sectional view illustrating an apparatus 1000 for manufacturing a semiconductor device, according to example embodiments.

Referring to FIG. 1, the apparatus 1000 for manufacturing a semiconductor device may include a process chamber 10, a substrate supporter 100, a distribution assembly 200, and a plasma generator 300. The apparatus 1000 for manufacturing a semiconductor device is configured to perform a semiconductor device manufacturing process and may perform, for example, a deposition process, an etching process, a cleaning process, or the like.

The process chamber 10 may be a chamber used for a semiconductor device manufacturing process, for example, a deposition process, an etching process, a cleaning process, or the like. For example, the process chamber 10 may be a plasma chamber for performing a plasma process, for example, a deposition process, an etching process, a cleaning process, or the like, on a processing object by using plasma. The process chamber 10 may include a plasma processing space 11 therein. An exhaust pipe 13 may be arranged in a lower portion of the process chamber 10 and may be connected to a vacuum pump 12. A gate valve 14, which opens and closes an opening 15, may be provided onto an outer sidewall of the process chamber 10, the opening 15 being in charge of carrying a substrate 101 in and out.

The substrate supporter 100 may support the substrate 101 while a semiconductor device manufacturing process is performed on the substrate 101. For example, the substrate supporter 100 may be configured to support the substrate 101 by vacuum-sucking the substrate 101. In addition, the substrate supporter 100 may function to adjust the temperature of the substrate 101 by heating or cooling the substrate 101.

The substrate supporter 100 may include a pedestal plate 110, a lift pin 140, and a pedestal temperature controller 117.

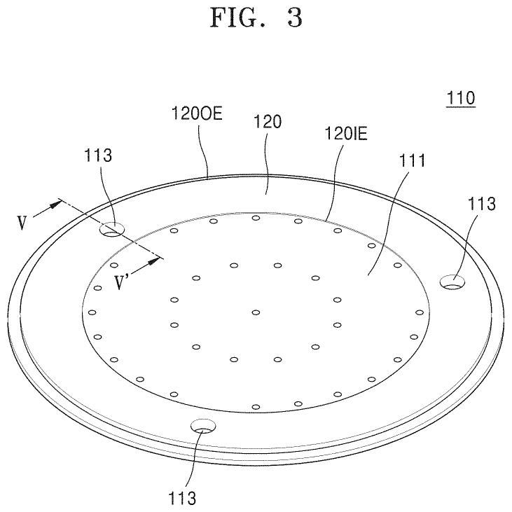

The pedestal plate 110 may have a circular plate shape, and the substrate 101 may be loaded on the pedestal plate 110. The pedestal plate 110 may be configured to be raised or lowered by a driving device 119. A stepped portion may be formed on an outer circumferential surface of the pedestal plate 110, and an edge ring 150 may be mounted on the stepped portion. For example, the pedestal plate 110 may include one of a dielectric, an insulator, a semiconductor, and a combination thereof. For example, the pedestal plate 110 may include alumina (Al₂O₃). The pedestal plate 110 will be described below in more detail with reference to FIGS. 3 to 5.

The lift pin 140 may penetrate the pedestal plate 110 and may raise and lower the substrate 101 relative to the pedestal plate 110. The lift pin 140 may be inserted into a lift pin hole (113 in FIG. 3) arranged in the pedestal plate 110 and may be raised and lowered inside the lift pin hole 113.

When the substrate 101, which is a processing object, is carried into or carried out of the process chamber 10, the lift pin 140 may protrude upwards from the pedestal plate 110 to be in a pin-up state and thus support the substrate 101. In addition, while the substrate 101 is processed in the process chamber 10, the lift pin 140 may be lowered below an upper surface of the pedestal plate 110 to be in a pin-down state and thus allow the substrate 101 to be placed on the pedestal plate 110.

The substrate supporter 100 may include the lift pin 140 in a suitable number for supporting the substrate 101. For example, the substrate supporter 100 may include three lift pins 140 that are radially spaced apart at regular intervals. In this case, the pedestal plate 110 may include the lift pin hole 113 in a number corresponding to the number of lift pins 140. For example, the pedestal plate 110 may include three lift pin holes 113 that are radially spaced apart at regular intervals.

The pedestal temperature controller 117 may control the temperature of the substrate 101 during a semiconductor device manufacturing process. For example, a channel 115 may be formed inside the pedestal plate 110 to allow a heat transfer fluid to flow. For example, the channel 115 may have a concentrical or spiral shape about a central axis of the pedestal plate 110. For example, the heat transfer fluid may include water, ethylene glycol, silicone oil, liquid Teflon, or a combination thereof.

The pedestal temperature controller 117 may adjust the temperature of the pedestal plate 110 and the temperature of the substrate 101, which is loaded on the pedestal plate 110, by adjusting the temperature and flow rate of the heat transfer fluid supplied to the channel 115 in the pedestal plate 110. The temperature of the pedestal plate 110 may be raised or lowered by the pedestal temperature controller 117, and the temperature of the substrate 101 may be adjusted by heat transfer between the substrate 101 and the pedestal plate 110.

The plasma generator 300 may generate plasma and supply the generated plasma to the process chamber 10.

In example embodiments, the plasma generator 300 may include a first electrode 310 and a second electrode 330, which are arranged on the distribution assembly 200. The first electrode 310 may be electrically insulated from the second electrode 330 by an insulator 320 arranged between the first electrode 310 and the second electrode 330. The first electrode 310 may be connected to a power supply unit 360 and receive power, which is applied thereto and needed for plasma generation, from the power supply unit 360. For example, the power supply unit 360 may apply, to the first electrode 310, radio frequency (RF) power in the form of an electromagnetic wave having a certain frequency and a certain intensity. The second electrode 330 may be connected to ground. The first electrode 310 may be apart from the second electrode 330 in a vertical direction, and a plasma generation space 340, in which plasma may be generated, may be formed between the first electrode 310 and the second electrode 330.

A gas supply unit 350 may supply a process gas to the plasma generation space 340. For example, the gas supply unit 350 may supply the process gas to the plasma generation space 340 via a gas introduction port formed in the first electrode 310. When the process gas is supplied to the plasma generation space 340, the power supply unit 360 may generate plasma in the plasma generation space 340 by applying power to the first electrode 310. The plasma generated in the plasma generator 300 may include a plurality of components. For example, the plasma may include radicals, ions, electrons, ultraviolet rays, and the like. The plasma generated in the plasma generation space 340 may be jetted to the distribution assembly 200 via a jet hole 331 of the second electrode 330.

The distribution assembly 200 may distribute the plasma supplied from the plasma generator 300 and may jet the distributed plasma to the plasma processing space 11 in the process chamber 10. For example, the distribution assembly 200 may radially diffuse the plasma introduced from the plasma generator 300 and may jet the plasma toward the substrate 101 loaded on the substrate supporter 100. For example, the distribution assembly 200 may be arranged on the process chamber 10 and may be mounted on a lower surface of the second electrode 330.

In example embodiments, the distribution assembly 200 may include a blocker plate 210 and a shower head 230.

The blocker plate 210 may be arranged between the second electrode 330 and the shower head 230. For example, the blocker plate 210 may be mounted on the lower surface of the second electrode 330 and may be accommodated in a recess space formed in the shower head 230. The blocker plate 210 may include a plurality of first through-holes 210H configured to cause plasma to pass therethrough. Through the first through-holes 210H, the plasma may pass through the blocker plate 210 and thus be jetted toward the shower head 230.

The blocker plate 210 may have a plate shape and may provide a diffusion space in which the plasma supplied from the plasma generator 300 may be diffused. Since the plasma supplied from the plasma generator 300 is radially diffused in the diffusion space between the second electrode 330 and the blocker plate 210, the plasma may be prevented from being jetted, with a high pressure, directly to the substrate 101.

The shower head 230 may be arranged above the substrate supporter 100, on which the substrate 101 is loaded. The shower head 230 may provide a diffusion space in which the plasma emitted via the first through-holes 210H of the blocker plate 210 may be diffused. That is, the plasma may be radially diffused in the diffusion space between the shower head 230 and the blocker plate 210.

The shower head 230 may include a distribution plate having a circular plate shape and a plurality of second through-holes 230H formed in the distribution plate. The second through-holes 230H may be configured to cause plasma to pass therethrough, and the plasma may be jetted to the plasma processing space 11 in the process chamber 10 via the second through-holes 230H.

In some example embodiments, the apparatus 1000 may further include a controller including a processor and a memory (not shown). The memory may be configured to store computer readable code that, when executed by the processor, configures the processor as a special purpose computer, to control one or more of the vacuum pump 12, the pedestal temperature controller 117, the driving device 119 to raise or lower the pedestal plate 110, the gas supply unit 350, and/or the power supply unit 360.

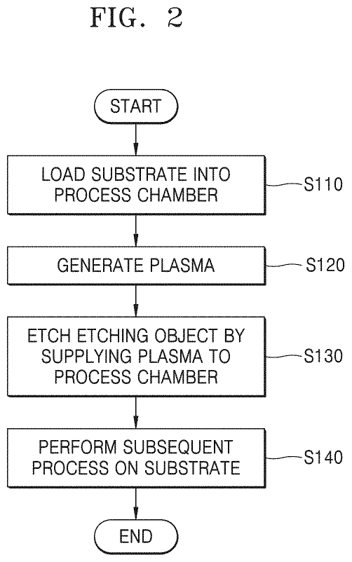

For example, the controller may be configured to control the apparatus 1000 to perform one or more operations included in the method of FIG. 2, discussed below.

FIG. 2 is a flowchart illustrating a method of manufacturing a semiconductor device including an etching method using the apparatus 1000 shown in FIG. 1.

Referring to FIGS. 1 and 2, in operation S110, the substrate 101 is loaded into the process chamber 10. For example, the substrate 101 may be loaded on the substrate supporter 100 in the process chamber 10 by opening the gate valve 14. The substrate supporter 100 may secure the substrate 101 loaded on the pedestal plate 110 by using, for example, a vacuum pressure.

Here, the substrate 101 may be a semiconductor substrate including a semiconductor material and may include a material layer formed on the substrate 101. The material layer formed on the substrate 101 may include an insulating layer and/or a conductive layer formed on the substrate 101 by various methods such as deposition, coating, plating, and the like. For example, the insulating layer may include an oxide layer, a nitride layer, an oxynitride layer, or the like, and the conductive layer may include a metal layer, a polysilicon layer, or the like. The material layer may include a single layer or a multi-layer, which is formed on the substrate 101. In addition, the material layer may be formed on the substrate 101 to have a certain pattern. For example, an etching object may be a material layer including silicon oxide on the substrate 101. Alternatively, the etching object may be a native oxide layer on the substrate 101. For reference, although the following description is made only regarding etching, the same methods, principles, and the like may also be applied to cleaning, and there may also be the same effects and the like in cleaning.

In operation S120, the plasma generator 300 may generate plasma. For example, the gas supply unit 350 may supply a process gas for plasma generation to the plasma generator 300, and the power supply unit 360 may apply appropriate power, thereby generating the plasma in the plasma generation space 340. The plasma may include a plurality of components, and at least one of the plurality of components may be mainly used to etch the etching object. For example, the plasma may include radicals, ions, electrons, ultraviolet rays, and the like.

For example, to perform an etching process on the material layer including silicon oxide on the substrate 101, the gas supply unit 350 may supply a source gas for etching to the plasma generator 300. For example, the gas supply unit 350 may supply a source gas including NH₃ and NF₄ to the plasma generator 300. In addition to the source gas for etching, the process gas supplied from the gas supply unit 350 may further include other process gases such as N₂, O₂, N₂O, NO, Ar, He, H₂, and the like.

In the plasma generator 300, NH₃ and NF₄ may form NH₄F and NH₄F.HF, which are etching sources, through a chemical reaction represented by Chemical Formula 1.

NF₃+NH₃→NH₄F+NH₄F.HF [Chemical Formula 1]

In operation S130, the apparatus 1000 may etch the etching object by supplying the plasma into the process chamber 10. The plasma generated in the plasma generator 300 may be introduced into the distribution assembly 200, and the distribution assembly 200 may radially diffuse the plasma. The distribution assembly 200 may jet the plasma, which is uniformly distributed on the whole, toward the substrate 101 loaded on the pedestal plate 110.

Here, the substrate supporter 100 may control the temperature of the substrate 101 to a suitable temperature for performing the etching process on the material layer including silicon oxide on the substrate 101. For example, the pedestal temperature controller 117 may maintain the temperature of the substrate 101 in a relatively low temperature range during the etching process for the material layer. For example, the pedestal temperature controller 117 may maintain the temperature of the substrate 101 at 100° C. or less. Alternatively, the pedestal temperature controller 117 may maintain the temperature of the substrate 101 at about 30° C. to about 50° C. In such a low temperature range, since an etching source, for example, NH₄F or NH₄.HF, for etching the material layer including silicon oxide is more easily adsorbed onto the material layer, an etch rate of the material layer may be increased.

NH₄F or NH₄F.HF, which is an etching source, may etch the material layer including silicon oxide through a chemical reaction represented by Chemical Formula 2 or 3.

NH₄F+SiO₂→(NH₄)₂SiF₆+H₂O [Chemical Formula 2]

NH₄F.HF+SiO₂→(NH₄)₂SiF₆+H₂O [Chemical Formula 3]

After the material layer including silicon oxide is etched, to remove solid-state (NH₄)₂SiF₆, which is a by-product remaining on the substrate 101, the substrate supporter 100 may heat the substrate 101 to a high temperature. For example, the substrate supporter 100 may heat the substrate 101 to 100° C. or more. Under a high temperature condition, (NH₄)₂SiF₆ in a solid state may be removed through a chemical reaction represented by Chemical Formula 4.

(NH₄)₂SiF₆(s)→SiF₄(g)+NH₃(g)+HF(g) [Chemical Formula 4]

In operation S140, a subsequent process may be performed on the substrate 101. A subsequent semiconductor process may include various processes. For example, the subsequent semiconductor process may include a deposition process, an etching process, an ion process, a cleaning process, and the like. Here, the deposition process may include various material layer formation processes such as chemical vapor deposition (CVD), sputtering, spin coating, and the like. The etching process may be an etching process using plasma as described above or may be an etching process not using plasma. The ion process may include processes such as ion implantation, diffusion, heat treatment, and the like. By performing the subsequent semiconductor process, integrated circuits and wiring lines for a semiconductor device required for the substrate 101 may be formed.

The subsequent semiconductor process may include a packaging process in which the semiconductor device is mounted on a printed circuit board and then sealed with a sealant. In addition, the subsequent semiconductor process may also include a test process in which the semiconductor device or a semiconductor package is tested. The semiconductor device or the semiconductor package may be completed by performing the subsequent semiconductor process.

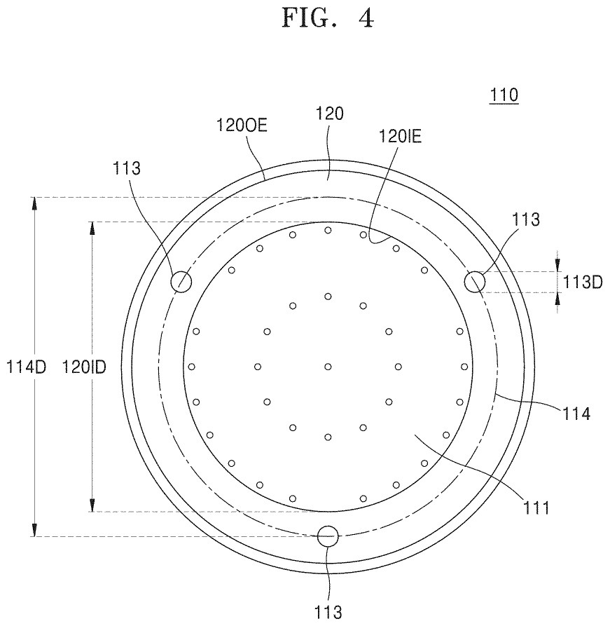

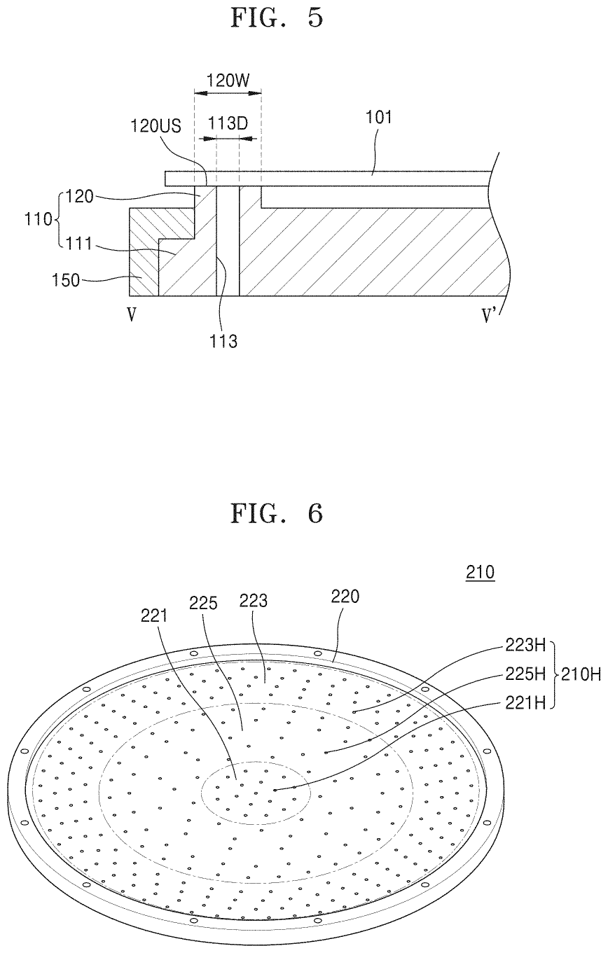

FIG. 3 is a perspective view illustrating the pedestal plate 110 of the substrate supporter 100 shown in FIG. 1. FIG. 4 is a plan view of the pedestal plate 110 of the substrate supporter 100 shown in FIG. 1, as viewed from above. FIG. 5 is a cross-sectional view of the pedestal plate 110, taken along a line V-V of FIG. 3.

Referring to FIGS. 3 to 5 together with FIG. 1, the pedestal plate 110 of the substrate supporter 100 may include a base 111 having a circular plate shape and a seal band 120 protruding from the base 111.

The seal band 120 is a portion of the pedestal plate 110, which contacts and supports the substrate 101, and may protrude from an upper surface of the base 111, which faces a bottom surface of the substrate 101. Since the substrate 101 is supported by the seal band 120, the upper surface of the base 111 may be apart from the bottom surface of the substrate 101 by as much as the height of the seal band 120.

The seal band 120 may include an upper surface 120US configured to surface-contact an edge region of the bottom surface of the substrate 101. The upper surface 120US of the seal band 120 may be flat, and a contact area between the seal band 120 and the substrate 101 may be equal to the area of the upper surface 120US of the seal band 120.

The seal band 120 may have a ring shape continuously extending from the upper surface of the base 111. For example, the seal band 120 may continuously extend along an edge of the base 111 or along an edge of the substrate 101 loaded on the pedestal plate 110. When the substrate 101 is loaded on the pedestal plate 110, the upper surface 120US of the seal band 120 may be in continuous contact with the bottom surface of the substrate 101.

The seal band 120 may surround a space defined by an inner wall of the seal band 120, the bottom surface of the substrate 101, and the upper surface of the base 111. A region inside the seal band 120 may be separated from a region outside the seal band 120. Thus, while the semiconductor device manufacturing process is performed, the seal band 120 may block a by-product generated in the region outside the seal band 120 from being introduced into the region inside the seal band 120. Therefore, the by-product may be inhibited (or, alternatively, prevented) from being adsorbed onto the bottom surface of the substrate 101.

In example embodiments, a plurality of lift pin holes 113 in the pedestal plate 110 may penetrate the base 111 and the seal band 120. The plurality of lift pin holes 113 may be located inside the seal band 120 and may be arranged between an inner edge 120IE of the seal band 120 and an outer edge 120OE of the seal band 120.

In example embodiments, the seal band 120 may have a constant width 120W in a radial direction thereof. Since the width 120W of the seal band 120 is constant, the width of the contact area between the seal band 120 and the substrate 101 may be radially constant. Here, a diameter 113D of each lift pin hole 113 may be less than the width 120W of the seal band 120 in the radial direction.

A pitch circle 114 of the plurality of lift pin holes 113 may refer to an imaginary circle passing through the center of each of the plurality of lift pin holes 113 on a plane. In example embodiments, an inner diameter 120ID of the seal band 120 may be less than a pitch circle diameter 114D of the pitch circle 114 of the plurality of lift pin holes 113. Here, since the plurality of lift pin holes 113 are located inside the seal band 120, the pitch circle 114 of the plurality of lift pin holes 113 may be located between the inner edge 120IE of the seal band 120 and the outer edge 120OE of the seal band 120.

Heat transfer between the pedestal plate 110 and the substrate 101 may be substantially performed by conductive heat transfer via the seal band 120. Thus, when the temperature of the pedestal plate 110 is adjusted into a low temperature range to perform a plasma process on the substrate 101, the temperature of an edge region of the substrate 101, which is in contact with the seal band 120, may be decreased. Here, the temperature of the edge region of the substrate 101 may be less than the temperature of a central region of the substrate 101.

For example, when an etch rate of silicon oxide on the edge region of the substrate 101 is less than an etch rate of silicon oxide on the central region of the substrate 101, the substrate supporter 100 may adjust the temperature of the substrate 101 such that the temperature of the edge region of the substrate 101 is less than the temperature of the central region of the substrate 101. As the temperature of the edge region of the substrate 101 decreases, the etch rate of the material layer including silicon oxide on the edge region of the substrate 101 increases and the etching process may be performed more uniformly between the central region and the edge region of the substrate 101.

In addition, since the amount of heat transferred between the pedestal plate 110 and the substrate 101 varies with the contact area between the substrate 101 and the seal band 120, etching process properties may be more uniform between the central region of the substrate 101 and the edge region of the substrate 101 by appropriately adjusting the area of the upper surface 120US of the seal band 120.

According to example embodiments, since the seal band 120 has the constant width 120W in the radial direction thereof, the transfer of conductive heat between the pedestal plate 110 and the substrate 101 may be uniformly performed in the edge region of the substrate 101. That is, since the seal band 120 of the pedestal plate 110 is in contact with the substrate 101 with a radially uniform width, temperature uniformity of the edge region of the substrate 101 may be improved and uniformity in the etching process for the edge region of the substrate 101 may be improved.

In addition, according to example embodiments, since the contact area between the seal band 120 of the pedestal plate 110 and the substrate 101 is increased due to the inner diameter 120ID of the seal band 120 being less than a pitch circle diameter 114D of the plurality of lift pin holes 113, the temperature of the edge region of the substrate 101 may be easily decreased, the material layer including silicon oxide on the edge region of the substrate 101 may be etched at a high etch rate.

FIG. 6 is a perspective view illustrating the blocker plate 210 according to example embodiments.

Referring to FIG. 6 together with FIG. 1, the blocker plate 210 may include a body 220 and the first through-holes 210H penetrating the body 220, the body 220 having a circular plate shape and forming an overall appearance of the blocker plate 210.

In example embodiments, the blocker plate 210 may include a single material. For example, the blocker plate 210 may include nickel (Ni). In this case, a material constituting an upper surface of the body 220 of the blocker plate 210, a material constituting a lower surface of the body 220 of the blocker plate 210, which is opposite to the upper surface of the body 220 of the blocker plate 210, and a material constituting an inner wall of the body 220 of the blocker plate 210, which is provided by each first through-hole 210H, may be identical to each other.

Surface roughness of the blocker plate 210 may influence a decomposition rate of a material diffused in the diffusion space provided by the blocker plate 210. For example, when an etching process is performed on the material layer including silicon oxide on the substrate 101, the plasma generator 300 may supply, to the distribution assembly 200, etching sources, for example, NH₄F and NH₄.HF, for etching the material layer. While NH₄F and NH₄F.HF are diffused along the blocker plate 210, hydrogen fluoride (HF), which is an etching source mainly participating in a removal reaction of silicon oxide, may be generated, and etch selectivity of silicon oxide relative to silicon nitride may be improved with an increasing generation rate of HF. Here, the etch selectivity may be defined as “an etching rate of an etching object”/“an etching rate of a non-etching object”.

According to example embodiments, the blocker plate 210 may include a single material of nickel, whereby the blocker plate 210 may have relatively low surface roughness. In this case, since the generation rate of HF, which is an etching source mainly participating in a removal reaction of silicon oxide, increases while NH₄F and NH₄F.HF diffuse along the blocker plate 210, the etch selectivity of silicon oxide relative to silicon nitride may be improved.

Generally, a blocker plate may include a plating layer on a certain member including a first material, the plating layer including a second material that is different from the first material. In this case, since surface roughness of the blocker plate changes as the plating layer of the blocker plate is peeled off, etch selectivity may vary with a change of the blocker plate over time. However, according to example embodiments, the blocker plate 210 includes a single material, whereby a change in the surface roughness of the blocker plate 210 over time may be reduced, and thus, the etch selectivity of silicon oxide relative to silicon nitride may be easily managed.

As shown in FIG. 6, the density of the first through-holes 210H of the blocker plate 210 may be different for each region of the blocker plate 210. Here, the density of holes in a particular region of the blocker plate 210 may refer to the number of holes formed in the particular region of the blocker plate 210 relative to the area of the particular region of the blocker plate 210. Thus, that the density of first holes is greater than the density of second holes may mean that the number of first holes is greater than the number of second holes, based on the same area in which the first or second holes are formed.

For example, the first through-holes 210H of the blocker plate 210 may include a plurality of first central through-holes 221H in a central region 221 of the body 220, a plurality of first edge through-holes 223H in an edge region 223 of the body 220, and a plurality of first intermediate through-holes 225H in an intermediate region 225 of the body 220.

The central region 221 of the body 220 may be a region including the center of the blocker plate 210. The intermediate region 225 of the body 220 may be a region between the central region 221 of the body 220 and the edge region 223 of the body 220 and may surround the central region 221 of the body 220. In addition, the edge region 223 of the body 220 may surround the intermediate region 225 of the body 220. For example, the central region 221 of the body 220 may be a region extending from the center of the blocker plate 210 by as much as a first length in the radial direction, the intermediate region 225 of the body 220 may be a region extending from a border between the central region 221 of the body 220 and the intermediate region 225 of the body 220 by as much as a second length in the radial direction, and the edge region 223 of the body 220 may be a region extending from a border between the intermediate region 225 of the body 220 and the edge region 223 of the body 220 by as much as a third length in the radial direction. For example, the first length of the central region 221, the second length of the intermediate region 225, and the third length of the edge region 223 may be equal to each other. Alternatively, the second length of the intermediate region 225 may be greater than each of the first length of the central region 221 and the third length of the edge region 223.

Here, the density of the plasma in the plasma processing space 11 of the process chamber 10 may be adjusted by adjusting the density of the first central through-holes 221H, the density of the first edge through-holes 223H, and/or the density of the first intermediate through-holes 225H.

More specifically, the plasma emitted via the first central through-holes 221H may substantially influence a plasma density near the central region of the substrate 101, the plasma emitted via the first edge through-holes 223H may substantially influence a plasma density near the edge region of the substrate 101, and the plasma emitted via the first intermediate through-holes 225H may substantially influence a plasma density near an intermediate region of the substrate 101 between the central region and the edge region of the substrate 101. Thus, properties of an etching process for the substrate 101 may be adjusted by adjusting the density of the first central through-holes 221H, the density of the first edge through-holes 223H, and/or the density of the first intermediate through-holes 225H.

In example embodiments, the density of the first central through-holes 221H, the density of the first edge through-holes 223H, and the density of the first intermediate through-holes 225H may be different from each other. For example, the first edge through-holes 223H may have a density that is greater than the density of the first central through-holes 221H. For example, the density of the first edge through-holes 223H may be about 1.5 times to about 3 times the density of the first central through-holes 221H. Alternatively, the density of the first edge through-holes 223H may be about 2 times the density of the first central through-holes 221H.

In addition, the density of the first intermediate through-holes 225H may be less than each of the density of the first central through-holes 221H and the density of the first edge through-holes 223H.

According to example embodiments, since the density of the first edge through-holes 223H is greater than the density of the first central through-holes 221H, and thus, the plasma density near the edge region of the substrate 101 is further increased, an etch rate of a material layer on the substrate 101 may be increased in the edge region of the substrate 101. In particular, when the etch rate in the edge region of the substrate 101 is less than the etch rate in the central region of the substrate 101, the etch rate of the material layer on the substrate 101 may be uniform on the whole by increasing the density of the first edge through-holes 223H.

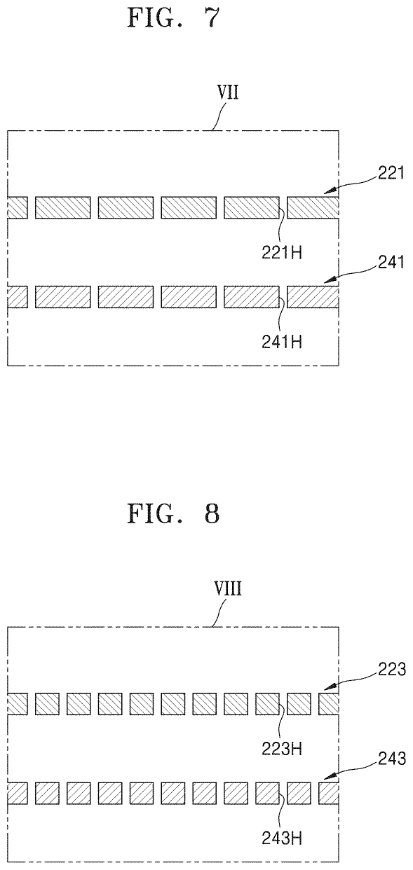

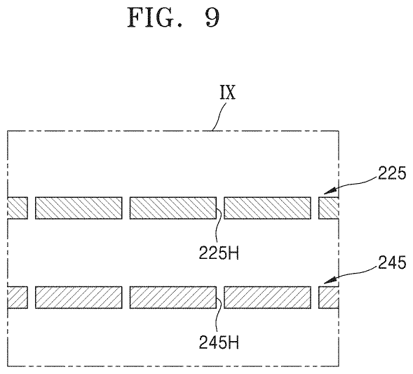

FIG. 7 is a cross-sectional view illustrating the blocker plate 210 and the shower head 230, which correspond to a region VII in FIG. 1. FIG. 8 is a cross-sectional view illustrating the blocker plate 210 and the shower head 230, which correspond to a region VIII in FIG. 1. FIG. 9 is a cross-sectional view illustrating the blocker plate 210 and the shower head 230, which correspond to a region IX in FIG. 1. FIG. 7 illustrates the central region 221 of the blocker plate 210 and a central region 241 of the shower head 230, FIG. 8 illustrates the edge region 223 of the blocker plate 210 and an edge region 243 of the shower head 230, and FIG. 9 illustrates the intermediate region 225 of the blocker plate 210 and an intermediate region 245 of the shower head 230.

Referring to FIGS. 7 to 9 together with FIG. 1, the second through-holes 230H of the shower head 230 may include a plurality of second central through-holes 241H in the central region 241 of the shower head 230, a plurality of second edge through-holes 243H in the edge region 243 of the shower head 230, and a plurality of second intermediate through-holes 245H in the intermediate region 245 of the shower head 230.

The central region 241 of the shower head 230 may be a region including the center of the shower head 230. The intermediate region 245 of the shower head 230 may be a region between the central region 241 of the shower head 230 and the edge region 243 of the shower head 230 and may surround the central region 241 of the shower head 230. In addition, the edge region 243 of the shower head 230 may surround the intermediate region 245 of the shower head 230.

As shown in FIGS. 7 to 9, the second through-holes 230H of the shower head 230 may be vertically aligned with the first through-holes 210H of the blocker plate 210. However, example embodiments of the inventive concepts are not limited thereto, and the second through-holes 230H of the shower head 230 may not be vertically aligned with the first through-holes 210H of the blocker plate 210 and may be horizontally offset therefrom.

Here, the density of the plasma in the plasma processing space 11 of the process chamber 10 may be adjusted by adjusting the density of the second central through-holes 241H, the density of the second edge through-holes 243H, and/or the density of the second intermediate through-holes 245H.

More specifically, the plasma emitted via the second central through-holes 241H may influence the plasma density near the central region of the substrate 101 similarly to the case of the first central through-holes 221H, the plasma emitted via the second edge through-holes 243H may influence the plasma density near the edge region of the substrate 101 similarly to the case of the first edge through-holes 223H, and the plasma emitted via the intermediate through-holes 245H may influence the plasma density near the intermediate region of the substrate 101 similarly to the case of the first intermediate through-holes 225H. Thus, properties of an etching process for the substrate 101 may be adjusted by adjusting the density of the second central through-holes 241H, the density of the second edge through-holes 243H, and/or the density of the second intermediate through-holes 245H.

In example embodiments, the second through-holes 230H of the shower head 230 may be formed to a density corresponding to the density of the first through-holes 210H of the blocker plate 210. For example, the density of the second central through-holes 241H of the shower head 230 may correspond to the density of the first central through-holes 221H of the blocker plate 210, the density of the second edge through-holes 243H of the shower head 230 may correspond to the density of the first edge through-holes 223H of the blocker plate 210, and the density of the second intermediate through-holes 245H of the shower head 230 may correspond to the density of the first intermediate through-holes 225H of the blocker plate 210.

Here, that the density of the second central through-holes 241H corresponds to the density of the first central through-holes 221H may mean that the proportion of the second central through-holes 241H in the second through-holes 230H is substantially equal to the proportion of the first central through-holes 221H in the first through-holes 210H. Similarly, that the density of the second edge through-holes 243H corresponds to the density of the first edge through-holes 223H may mean that the proportion of the second edge through-holes 243H in the second through-holes 230H is substantially equal to the proportion of the first edge through-holes 223H in the first through-holes 210H, and that the density of the second intermediate through-holes 245H corresponds to the density of the first intermediate through-holes 225H may mean that the proportion of the second intermediate through-holes 245H in the second through-holes 230H is substantially equal to the proportion of the first intermediate through-holes 225H in the first through-holes 210H.

In example embodiments, in correspondence with that the density of the first edge through-holes 223H in the blocker plate 210 is greater than the density of the first central through-holes 221H in the blocker plate 210, the density of the second edge through-holes 243H in the shower head 230 may be greater than the density of the second central through-holes 241H in the shower head 230. In addition, in correspondence with that the density of the first intermediate through-holes 225H in the blocker plate 210 is less than each of the density of the first central through-holes 221H and the density of the first edge through-holes 223H in the blocker plate 210, the density of the second intermediate through-holes 245H in the shower head 230 may be less than each of the density of the second central through-holes 241H and the density of the second edge through-holes 243H in the shower head 230.

According to example embodiments, since the density of the first edge through-holes 223H in the blocker plate 210 is greater than the density of the first central through-holes 221H in the blocker plate 210 and, in correspondence with this, the density of the second edge through-holes 243H in the shower head 230 is greater than the density of the second central through-holes 241H in the shower head 230, the plasma density near the edge region of the substrate 101 may be further increased, and thus, the etch rate of the material layer on the substrate 101 may be increased in the edge region of the substrate 101. In particular, when the etch rate in the edge region of the substrate 101 is less than the etch rate in the central region of the substrate 101, the etch rate of the material layer on the substrate 101 may be uniform on the whole by increasing the density of the first edge through-holes 223H of the blocker plate 210 and the density of the second edge through-holes 243H of the shower head 230.

As discussed above, in example embodiments, an apparatus 1000 may include the pedestal plate 110 having the seal band 120 (i) with an inner diameter 120ID less than a pitch circle diameter 114D of a pitch circle 114 of lift pin holes 113, and (ii) having the constant width 120W in a radial direction thereof. Therefore, the temperature in the edge region of the substrate 101 may be easily decreased and maintained uniform. Further, in one or more example embodiments, the apparatus 1000 may include a distribution assembly 200 having a blocker plate 210 formed entirely of nickel (Ni) and, thus “the etch selectivity of silicon oxide relative to silicon nitride may be improved.” See [0075] and [0076].

While example embodiments of the inventive concepts have been particularly shown and described with reference to some example embodiments thereof, it will be understood by those skilled in the art that various changes in form and details may be made therein without departing from the spirit and scope of the following claims. In addition, it should be understood that particular terms used herein are only for the purpose of describing the example embodiments and are not intended to limit the example embodiments of the inventive concepts. Therefore, the scope of example embodiments of the inventive concepts should be defined by the accompanying claims and equivalents thereof

1. An apparatus configured to manufacture a semiconductor device, the apparatus comprising:
a process chamber having a plasma processing space therein; and
a substrate supporter in the process chamber, the substrate supporter configured to support a substrate, the substrate supporter including,
a base having a plurality of lift pin holes therein such that the plurality of lift pin holes are arranged with a pitch circle diameter, the plurality of lift pin holes each configured to accommodate a lift pin; and
a seal band having a ring shape and protruding from the base, the seal band having an inner diameter less than the pitch circle diameter of the plurality of lift pin holes.

2. The apparatus according to claim 1, wherein the plurality of lift pin holes are configured to penetrate the seal band.

3. The apparatus according to claim 2, wherein the plurality of lift pin holes are between an outer edge of the seal band and an inner edge of the seal band.

4. The apparatus according to claim 2, wherein a width of the seal band in a radial direction thereof is greater than a diameter of each of the plurality of lift pin holes.

5. The apparatus according to claim 1, wherein a width of the seal band in a radial direction thereof is constant.

6. The apparatus according to claim 1, wherein the substrate supporter further comprises:
a pedestal temperature controller configured to adjust a temperature of the substrate loaded on the substrate supporter.

7. The apparatus according to claim 1, further comprising:
a plasma generator configured to generate plasma; and
a distribution assembly configured to diffuse the plasma supplied from the plasma generator, and to jet the plasma to the plasma processing space.

8. The apparatus according to claim 7, wherein the distribution assembly comprises:
a blocker plate configured to diffuse the plasma supplied from the plasma generator, the blocker plate including a body having a plate shape and first through-holes penetrating the body; and
a shower head configured to diffuse the plasma jetted via the first through-holes of the blocker plate, the shower head including second through-holes configured to jet the plasma to the plasma processing space.

9. The apparatus according to claim 8, wherein the body of the blacker plate comprises:
a single material.

10. The apparatus according to claim 8, wherein the first through-holes comprise:
a plurality of first central through-holes in a central region of the blocker plate; and
a plurality of first edge through-holes in an edge region of the blocker plate, wherein
a first density of the plurality of first central through-holes is different from a second density of the plurality of first edge through-holes.

11. The apparatus according to claim 10, wherein the second density of the plurality of first edge through-holes is greater than the first density of the plurality of first central through-holes.

12.-13. (canceled)

14. An apparatus configured to manufacture a semiconductor device, the apparatus comprising:
a process chamber having a plasma processing space therein; and
a substrate supporter in the process chamber, the substrate supporter configured to support a substrate, the substrate supporter including,
a base; and
a seal band having a ring shape and protruding from the base, the seal band having a constant width in a radial direction thereof.

15. The apparatus according to claim 14, further comprising:
a plurality of lift pins configured to penetrate respective ones of a plurality of lift pin holes in the substrate supporter, the plurality of lift pin holes extending into the seal band.

16. The apparatus according to claim 15, wherein the plurality of lift pin holes are arranged between an outer edge of the seal band and an inner edge of the seal band, wherein
a width of the seal band in the radial direction is greater than a diameter of each of the plurality of lift pin holes.

17.-18. (canceled)

19. The apparatus according to claim 14, further comprising:
a plasma generator configured to generate plasma;
a blocker plate having a plate shape, the blocker plate being above the process chamber, the blocker plate configured to radially diffuse the plasma supplied from the plasma generator; and
a shower head between the blocker plate and the substrate supporter, the shower head configured to jet the plasma to the substrate on the substrate supporter by diffusing the plasma supplied from the blocker plate.

20. The apparatus according to claim 19, wherein the blocker plate comprises:
a body and through-holes penetrating the body, the body being formed of nickel.

21. (canceled)

22. An apparatus configured to manufacture a semiconductor device, the apparatus comprising:
a process chamber having a plasma processing space therein;
a substrate supporter in the process chamber, the substrate supporter configured to support a substrate;
a plasma generator configured to generate plasma;
a blocker plate configured to diffuse the plasma supplied from the plasma generator, the blocker plate including a body having first through-holes therethrough, the body being formed of nickel; and
a shower head configured to diffuse the plasma jetted via the first through-holes of the blocker plate, the shower head having second through-holes therein, the shower head configured to jet the plasma to the plasma processing space via the second through-holes.

23. The apparatus according to claim 22, wherein the first through-holes comprise:
a plurality of first central through-holes in a central region of the blocker plate;
a plurality of first edge through-holes in an edge region of the blocker plate; and
a plurality of first intermediate through-holes in an intermediate region of the blocker plate between the central region of the blocker plate and the edge region of the blocker plate, wherein
a first density of the plurality of first central through-holes, a second density of the plurality of first edge through-holes, and a third density of the plurality of first intermediate through-holes are different from each other.

24. The apparatus according to claim 23, wherein the second density of the plurality of first edge through-holes is greater than the first density of the plurality of first central through-holes.

25. (canceled)

26. The apparatus according to claim 23, wherein the second through-holes comprise:
a plurality of second central through-holes in a central region of the shower head, the plurality of second central through-holes having a density corresponding to the first density of the plurality of first central through-holes;
a plurality of second edge through-holes in an edge region of the shower head, the plurality of second edge through-holes having a density corresponding to the second density of the plurality of first edge through-holes; and
a plurality of second intermediate through-holes in an intermediate region of the shower head between the central region of the shower head and the edge region of the shower head, the plurality of second intermediate through-holes having a density corresponding to the third density of the plurality of first intermediate through-holes.

27. (canceled)
